(19) United States
(12) Patent Application Publication
(10) Pub. No.: US 2011/0093753 A1
(43) Pub. Date: Apr. 21, 2011

(54) PHASE CALIBRATION CIRCUIT, MEMORY CARD CONTROL DEVICE, AND PHASE CALIBRATION METHOD

(75) Inventor: Kenichi TAKAGI, Kanagawa (JP)

(73) Assignee: RENESAS ELECTRONICS CORPORATION, Kanagawa (JP)

(21) Appl. No.: 12/907,563

(22) Filed: Oct. 19, 2010

(30) Foreign Application Priority Data
Oct. 20, 2009 (JP) 2009-241115

(51) Int. Cl. G06F 11/10; H03L 7/06; G06F 11/07

(52) U.S. Cl. 714/746; 327/156; 714/E11.032; 714/E11.023

(57) ABSTRACT

Provided is a phase calibration circuit to suppress degradation of transfer efficiency when reading data from a memory card. The phase calibration circuit includes a receive clock generator that generates clock signals including a first clock signal (FCS) with a phase shifted with respect to a base clock signal, a second clock signal with a phase advanced with respect to the FCS, and a third clock signal with a phase delayed with respect to the FCS; a determination unit that acquires data blocks, each of which including a data body and detection information for detecting an error, in accordance with the clock signals, determines whether an error occurs by using the detection information of the data blocks, and outputs determination results; and a phase adjustment unit that instructs the receive clock generator to adjust a phase of the FCS depending on the determination results.

### INCORPORATION BY REFERENCE

This application is based upon and claims the benefit of priority from Japanese patent application No. 2009-241115, filed on Oct. 20, 2009, the disclosure of which is incorporated herein in its entirety by reference.

### BACKGROUND

1. Field of the Invention

This invention relates to a memory card control device, and particularly to a phase calibration circuit and a phase calibration method to perform clock control when reading data from a memory card.

2. Description of Related Art

A memory card control device (which is also referred to hereinafter as “host controller”) supplies a transfer clock signal (base clock signal) for communicating data with the memory card. The memory card communicates data with the memory card control device based on the transfer clock signal that is received. When reading data from the memory card, the host controller acquires data transferred from the memory card in accordance with a clock signal synchronized with the transfer clock signal.

However, because the transfer clock signal supplied to the memory card and the clock signal to acquire read-out data are the same, it is difficult to perform a registration. That is to say, a clock signal (transfer clock signal) supplied to the memory card and a clock signal (acquisition clock signal) supplied to a register to acquire data from the memory card by a host have a given phase difference because these clocks are distributed via respective distribution circuits. The registration is to perform a fine adjustment of the clock signal such as appending a delay to the clock signal used for acquiring data, advancing a phase of the transfer clock signal supplied to the memory card in order to acquire data with certainty from the memory card in designing actual LSI (Large Scale Integration). This registration becomes more difficult with increasing processing speed.

For example, Japanese Unexamined Patent Application Publication No. 2004-192488 discloses a data processor to eliminate an access error due to a propagation delay of a clock signal and data. In this example, as shown in FIG. 9, selectors 32 and 35 are able to select one of a rising edge and a falling edge of a clock signal supplied to the memory card and the read-out data is acquired from the memory card at one of the rising edge and the falling edge that is selected. This makes it possible to adjust a timing to acquire the read-out data at a timing shifted by a half cycle of the clock signal.

It is also possible to switch frequencies of the clock signal by a frequency control circuit 13 and to adjust the timing in conjunction with switching of the frequencies. To adjust the timing is implemented by switching data acquisition on the rising edge of the clock signal and data acquisition on the falling edge of the clock signal depending on a read error of the read-out data. To adjust the timing is also implemented by changing the clock signal from a high-frequency wave to a low-frequency wave depending on the read error of the read-out data.

For adjusting the timing, registers D1 and D2 where CPU or the like can access are used. One of the rising edge of the clock signal and the falling edge of the clock signal is determined depending on control data set to the register D1 for acquiring the read-out data. One of the high-frequency wave and the low-frequency wave for the clock signal is determined depending on control data set to the register D2.

Detection of the read error is performed by using CRC (cyclic redundancy check) code or the like appended to the read data.

However a memory controller disclosed in Japanese Unexamined Patent Application Publication No. 2004-192488 cannot address propagation delay variation of the read-out data caused by variation of voltage or temperature after determination of an acquiring edge of the read-out data or determination of the frequency of the clock signal. When a read error of the read-out data occurs due to the propagation delay variation of the read-out data, there is a need to perform the determination of edge of the clock signal to acquire the read-out data and the determination of the frequency of the clock signal again. For this reason, an intended data transfer is suspended during these determinations. This results in degradation of transfer efficiency.

Further, in general, it is preferable that the frequency of the transfer clock signal is the maximum frequency specified by a specification employed by the memory card. On the other hand, in the technique disclosed in Japanese Unexamined Patent Application Publication No. 2004-192488, the frequency adjustment of the clock signal only changes from the high-frequency wave to the low-frequency wave. Hence, there is a possibility that the memory controller cannot operate with the maximum frequency of the specification.

### SUMMARY

The present inventor has found a problem that the degradation of transfer efficiency is caused when data is read from the memory card in the related art.

A first exemplary aspect of the present invention is a phase calibration circuit that includes a receive clock generator, a determination unit, and a phase adjustment unit. The receive clock generator generates a plurality of clock signals including at least a first clock signal with a phase shifted with respect to a base clock signal, a second clock signal with a phase advanced with respect to the first clock signal, and a third clock signal with a phase delayed shift with respect to the first clock signal. The determination unit acquires data blocks, each of which including a data body and detection information for detecting an error, in accordance with the plurality of clock signals, determines whether an error occurs by using the detection information, and outputs a plurality of determination results including at least a first determination result obtained by determining a data block acquired in accordance with the first clock signal, a second determination result obtained by determining a data block acquired in accordance with the second clock signal, and a third determination result obtained by determining a data block acquired in accordance with the third clock signal. The phase adjustment unit instructs the receive clock generator to adjust a phase of the first clock signal depending on the plurality of the determination results.

As described above, the phase calibration circuit achieves an interface to transfer the data block including the data body and the detection information (for example, CRC code) using the base clock signal. Further, the phase calibration circuit serially receives data blocks in accordance with the first, second and third clock signals and detects a read error occurrence by using the detection information of the received data block. The phase adjustment unit adjusts a phase difference between the first, second and third clock signals and the base clock signal depending on the read error occurrence. These configurations enable to perform a phase adjustment of the first clock signal which is a receive clock signal for each reception of the data block. This makes it possible to suppress the read error occurrence. Further, there is no need to set a particular adjustment period to correct the phase of the receive clock signal. As a result, it is possible to suppress the degradation of data transfer efficiency.

A second exemplary aspect of the present invention is a memory card control device that includes the phase calibration circuit described above and a memory holding a data body.

A third exemplary aspect of the present invention is a phase calibration method that includes generating a plurality of clock signals including at least a first clock signal with a phase shifted with respect to a base clock signal, a second clock signal with a phase advanced with respect to the first clock signal, and a third clock signal with a phase delayed with respect to the first clock signal, acquiring data blocks, each of which including a data body and detection information for detecting an error, in accordance with the plurality of clock signals, determining whether an error occurs by using the detection information, outputting a plurality of determination results including at least a first determination result obtained by determining a data block acquired in accordance with the first clock signal, a second determination result obtained by determining a data block acquired in accordance with the second clock signal, and a third determination result obtained by determining a data block acquired in accordance with the third clock signal, and adjusting a phase of the first clock signal depending on the plurality of the determination results.

According to an exemplary aspect of the present invention, it is possible to suppress the degradation of transfer efficiency when data is read from the memory card.

### BRIEF DESCRIPTION OF THE DRAWINGS

The above and other exemplary aspects, advantages and features will be more apparent from the following description of certain exemplary embodiments taken in conjunction with the accompanying drawings, in which:

FIG. 1 is a block diagram showing an exemplary configuration of a memory card control device according to this invention;

FIG. 2 is a block diagram showing an exemplary configuration of a memory card control device according to a first exemplary embodiment of this invention;

FIG. 3 is a view to explain a resolution capability to be needed for a phase adjustment;

FIG. 4 is a pattern diagram showing a timing of a read operation to acquire a data block transferred from a memory card;

FIG. 5 is a flowchart showing an error detecting operation in the read operation to acquire the data block;

FIG. 6 is a pattern diagram showing a timing of a write operation to write the data block to the memory card;

FIG. 7 is a pattern diagram showing a timing of an access operation without data transfer to the memory card;

FIG. 8 is a view to explain a phase adjustment example of first, second and third clock signals; and

FIG. 9 is a block diagram showing a configuration of a memory card control device disclosed in Japanese Unexamined Patent Application Publication No. 2004-192488.

### DETAILED DESCRIPTION OF THE EXEMPLARY EMBODIMENTS

Exemplary embodiments of the present invention will be described hereinbelow with reference to the drawings. The following description and the drawings are appropriately shortened and simplified to clarify the explanation. In the drawings, the identical reference symbols denote structural elements having identical configurations or functions, or corresponding parts, and the redundant explanation thereof is omitted.

This invention has an exemplary feature to adjust a phase (calibration) of a receive clock signal when acquiring a data block read from a memory card in a memory card control device. Note that, the data block includes a data body and detection information for detecting an error.

The data body is data read from the memory card upon a data reading request by a read command which the memory card control device issues. The data body is transferred from the memory card to the memory card control device and acquired by the memory card control device. In the following explanation, an exemplary system will be explained where the memory card control device (a phase calibration circuit) adjusts the phase of the receive clock signal when the data body is one of read data and response data. The read data is data read from the memory card and the response data is data to respond to a command transmitted from the memory card control device by the memory card.

The detection information is information to detect whether a read error occurs in the data body. An error detecting code, an error correcting code or the like may be used as the detection information. A CRC code may be used, for example.

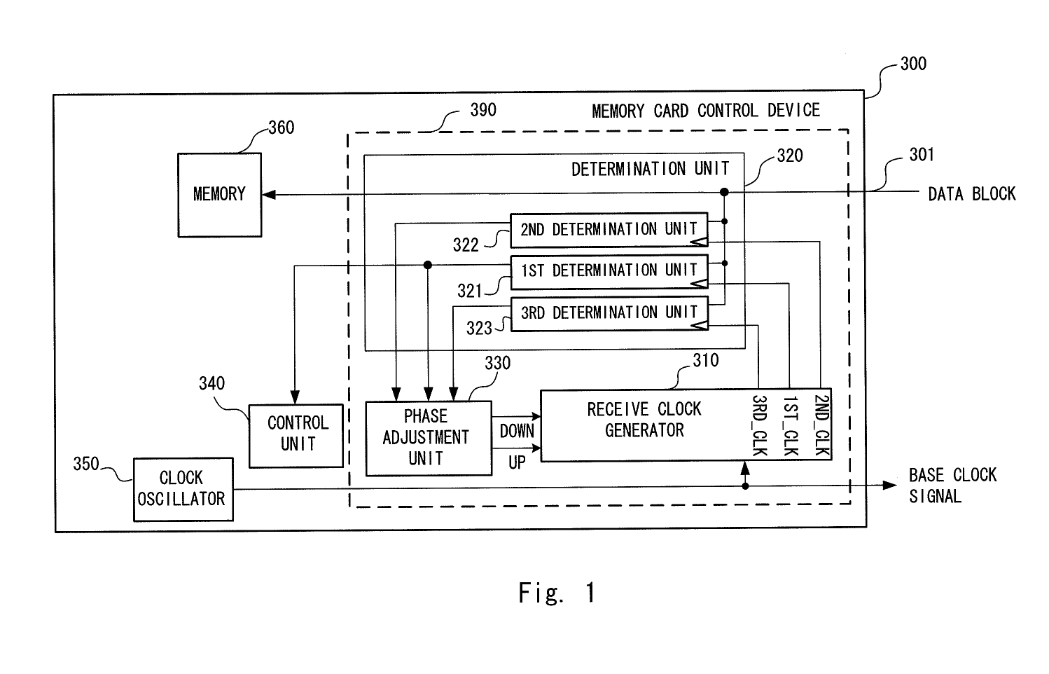

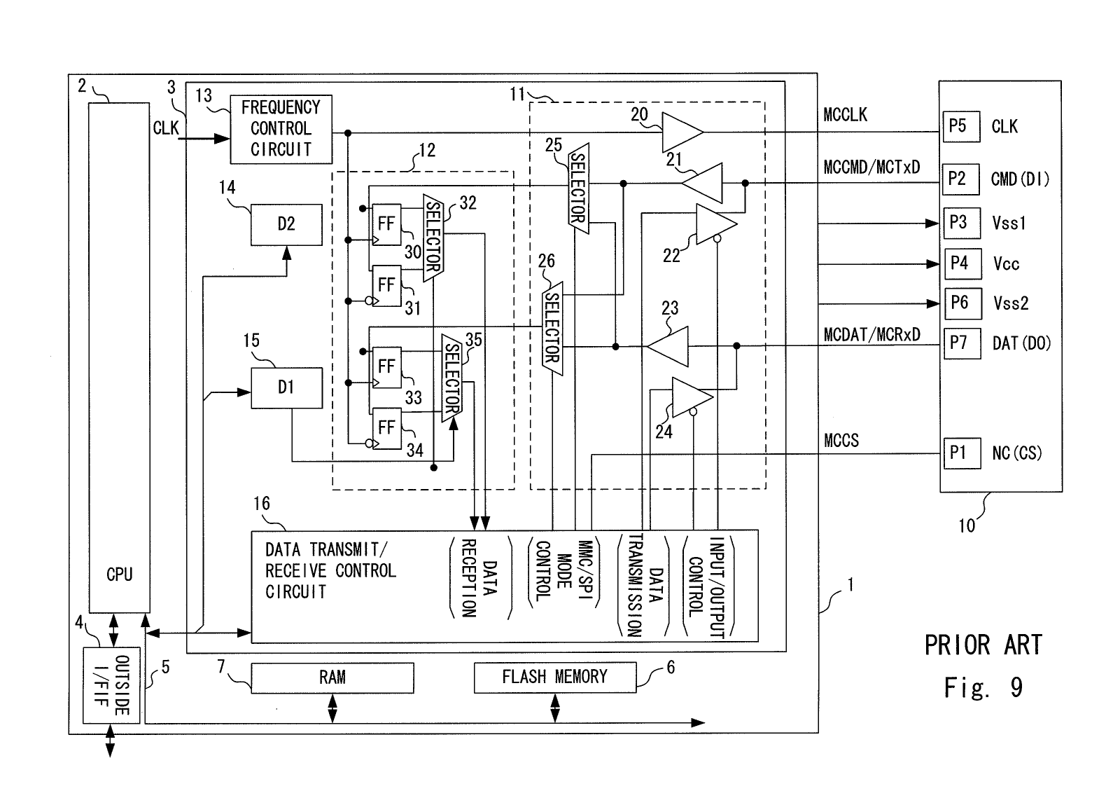

FIG. 1 is a block diagram showing an outline of an exemplary configuration of a memory card control device according to this invention. A memory card control device 300 includes a receive clock generator 310, a determination unit 320, a phase adjustment unit 330, a control unit 340, a clock oscillator 350, and a memory 360. Although the data block is generally transferred from the memory card to the memory card control device 300 by using a plurality of buses, one bus 301 is shown in FIG. 1 for simplification of explanation. The memory card control device 300 corresponds to a memory card interface controller 3 in FIG. 9.

The receive clock generator 310 receives a base clock signal from the clock oscillator 350 and generates a plurality of clock signals including a first clock signal with a phase shifted with respect to the base clock signal, a second clock signal with a phase advanced with respect to the first clock signal, and a third clock signal with a phase delayed with respect to the first clock signal. In FIG. 1, the first, second and third clock signals are shown as 1ST_CLK, 2ND_CLK, and 3RD_CLK, respectively. The first clock signal is a receive clock signal (clock signal for receiving) to receive (to acquire) the data block transferred from the memory card. The receive clock generator 310 adjusts a phase of the first clock signal to generate the second and third clock signals. Although the receive clock generator 310 generates three-phase clock signal in this example, the receive clock is not limited to this.

The determination unit 320 determines whether a read error occurs in the data blocks acquired in accordance with the plurality of the clock signals by using the data bodies and the detection information and outputs determination results to the phase adjustment unit 330. Specifically, the determination unit 320 acquires the data block transferred from the memory card in accordance with each of the first, second and third clock signals and determines whether a read error occurs by using the data bodies and the detection information. Then, the determination unit 320 outputs a first determination result obtained by determining the data block acquired in accordance with the first clock signal, a second determination result obtained by determining the data block acquired in accordance with the second clock signal, and a third determination result obtained by determining the data block acquired in accordance with the third clock signal to the phase adjustment unit 330. In addition, the first determination result is output to the control unit 340.

FIG. 1 shows a case where the determination unit 320 includes a first determination unit 321, a second determination unit 322, and a third determination unit 323. The first determination unit 321 generates and outputs the first determination result obtained by determining the data block acquired in accordance with the first clock signal. The second determination unit 322 generates and outputs the second determination result obtained by determining the data block acquired in accordance with the second clock signal. The third determination unit 323 generates and outputs the third determination result obtained by determining the data block acquired in accordance with the third clock signal.

The phase adjustment unit 330 instructs the receive clock generator 310 to adjust the phase of the first clock signal depending on the plurality of the determination results. Specifically, the phase adjustment unit 330 compares the plurality of the determination results and determines whether a phase adjustment is needed. The phase adjustment unit 330 instructs the receive clock generator 310 to adjust the phase adjustment. Then, the receive clock generator 310 shifts the phase of the first clock signal and shifts phases of the second and third clock signals depending on the first clock signal. As a result, a timing when the determination unit 320 acquires the data block is adjusted.

At a reception end to acquire the data blocks by the determination unit 320, the control unit 340 outputs an instruction to compare the plurality of the determination results (phase comparison) to the phase adjustment unit 330. The control unit 340 calculates the timing of the reception end by counting from a point to start a reception of the data block by the number corresponding to the length of the data block by a unit of the base clock signal. The phase adjustment unit 330 instructs the receive clock generator 116 to change a phase when there is a need to correct a phase depending on the instruction from the control unit 340. The control unit 340 detects an error occurrence based on the first determination result. When an error occurs in acquiring the data blocks (receiving the data blocks), the control unit 340 informs CPU (Central Processing Unit) arranged outside the memory card control device 300 of processing such as a deletion of the data body stored to the memory 360 or a reissue of a command transmitted from the memory card control device.

The clock oscillator 350 generates the base clock signal (transfer clock signal) and supplies the base clock signal to the receive clock generator 310 and the memory card. FIG. 1 shows the case where the clock oscillator 350 is arranged in the memory card control device 300. It is not limited to this configuration. The memory card control device 300 may be composed of elements without the clock oscillator 350 and may receive the base clock signal from an outside.

The memory 360 stores the data body acquired by the determination unit 320.

The phase calibration circuit 390 is mounted on the memory card control device 300 and has a function to adjust a timing to acquire the data block transferred from the memory card. The phase calibration circuit 390 shown in FIG. 1 at least includes the receive clock generator 310, the determination unit 320, and the phase adjustment unit 330.

Although the phase adjustment unit 330 and the control unit 340 are separately provided in FIG. 1, the control unit 340 may include a function corresponding to the phase adjustment unit 330, or the phase adjustment unit 330 may be arranged in the control unit 340.

By arranging the phase calibration circuit 390 as shown in FIG. 1, the memory card control device 300 can perform the phase adjustment of the receive clock signal with each reception of the data block. Therefore, it is possible to suppress a read error occurrence. Further, there is no need to set a particular adjusting (calibration) period to correct the phase of the receive clock signal. As a result, it is possible to suppress the degradation of transfer efficiency.

### First Exemplary Embodiment

A first exemplary embodiment describes a case where redundant data as the detection information for detecting an error is appended to the data body transferred from the memory card, and specifically the CRC code appended to the data block, for example.

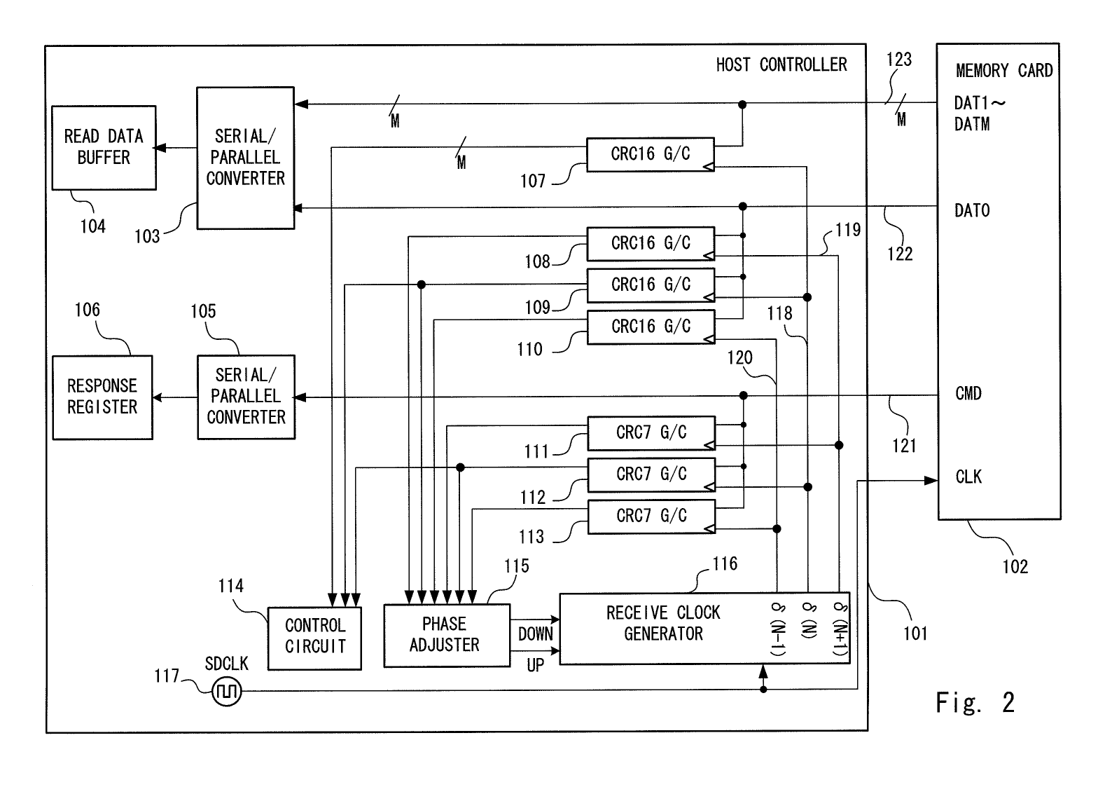

FIG. 2 is a block diagram showing an exemplary configuration of a memory card control device (host controller) according to the first exemplary embodiment of this invention. FIG. 2 shows an exemplary configuration of a host controller 101 as a specific example of the memory card control device 300 shown in FIG. 1. FIG. 2 also shows a memory card 102 for clarifying a relationship between the host controller 101 and the memory card 102. The host controller 101 transmits and receives the data block to/from the memory card 102. In the following explanation, the response data is transferred via a bus 121 connected to a terminal CMD of the memory card 102, and the read data is transferred via buses 122 and 123 connected to terminals DAT0 to DATM (M is an integer of zero or more) of the memory card 102.

Each structure element of FIG. 2 corresponds to that of FIG. 1 as follows. In the host controller 101, the receive clock generator 310 corresponds to a receive clock generator 116. The phase adjustment unit 330 corresponds to a phase adjuster 115. The control unit 340 corresponds to a control circuit 114. The clock oscillator 350 corresponds to a SDCLK 117. The memory 360 is composed of a serial/parallel converter 103, a read data buffer 104, a serial/parallel converter 105, and a response register 106. FIG. 2 shows the case where the SDCLK 117 is arranged in the host controller 101. It is not limited to this configuration. The host controller 101 may be composed of elements without the SDCLK 117 and may receive the base clock from an outside.

Further, the determination unit 320 corresponds to three CRC16 generator/checker units 108 to 110 to acquire the read data as the data body and three CRC7 generator/checker units 111 to 113 to acquire the response data for responding to a command as the data body. Specifically, the determination unit 320 includes the CRC16 generator/checker unit (first read data determination unit) 109 and the CRC7 generator/checker unit 107 (first response data determination unit) 112 which acquire the data blocks in accordance with the first clock signal, the CRC16 generator/checker unit (second read data determination unit) 108 and the CRC7 generator/checker unit (second response data determination unit) 111 which acquire the data blocks in accordance with the second clock signal, and the CRC16 generator/checker unit (third read data determination unit) 110 and the CRC7 generator/checker unit (third response data determination unit) 113 which acquire the data blocks in accordance with the third clock signal.

Furthermore, the host controller 101 includes a CRC16 generator/checker unit 107.

Note that in FIG. 2, “CRC16 generator/checker unit” is shown as “CRC16 G/C” and “CRC7 generator/checker unit” is shown as “CRC7 G/C”. Further, the CRC16 generator/checker unit and the CRC7 generator/checker unit may be collectively referred to as “CRC generator/checker”.

The receive clock generator 116 generates a first clock signal δ(N) by shifting the phase of the base clock signal supplied from the SDCLK 117 by a predetermined amount. Note that, the predetermined phase is set to a value which depends on a data output timing of the memory card, a distance (flight time) between the host controller 101 and the memory card 102 or the like. A variable number N is a positive integer to indicate an order of clock signals. The receive clock generator 116 generates a second clock signal δ(N+1) by advancing the phase of the first clock signal α(N) by a predetermined adjusting phase and a third clock signal δ(N−1) by delaying the phase of the first clock signal δ(N) by the predetermined adjusting phase. The predetermined adjusting phase is a given value (unit) for shifting a phase in order to generate clock signals based on the first clock signal δ(N) and held in the receive clock generator 116.

The first clock signal δ(N) is supplied to the CRC16 generator/checker units 107 to 110 and the CRC7 generator/checker units 111 to 113 via a clock signal line 118. In the same manner, the second clock signal δ(N+1) is supplied via a clock signal line 119, and the third clock signal δ(N−1) is supplied via a clock signal line 120.

As described above, the receive clock generator 116 generates three-phase receive clock signal including the first, second and third clock signals obtained by changing a phase of the base clock signal supplied to the memory card 102.

Each of the CRC16 generator/checker units 107 to 110 is a 16-bit CRC generator/checker. Each of the CRC7 generator/checker units 111 to 113 is a 7-bit CRC generator/checker. The 16-bit CRC generator/checker and 7-bit CRC generator/checker detect a read error occurrence.

Each of the CRC7 generator/checker units 111 to 113 is a CRC generator/checker to perform CRC calculation (generation) and check (comparison) to the data CMD (response data to respond to the command) in synchronization with the second, first and third clock signals, respectively. Because 7-bit CRC code is appended to a data transfer of the data CMD, the CRC7 generator/checker units 111 to 113 calculate 7-bit CRC code of the data CMD to perform comparison. The data CMD is transferred via a bus (command bus signal line) 121 from the memory card 102 and acquired by the CRC7 generator/checker units 111 to 113. The CRC7 generator/checker units 111 to 113 perform the CRC calculation and check and output determination results (first, second and third determination results) obtained by determining whether a read error occurs to the phase adjuster 115.

Each of the CRC16 generator/checker units 108 to 110 is a CRC generator/checker to perform CRC calculation (generation) and check (comparison) to data DAT0 (one of the read data) in synchronization with the second, first and third clock signals, respectively. Because 16-bit CRC code is appended to a data transfer of the data DAT0, the CRC16 generator/checker units 108 to 110 calculate 16-bit CRC code of the data DAT0 to perform comparison. The data DAT0 (data bus signal) is transferred via a bus (data bus signal line) 122 from the memory card 102 and acquired by the CRC16 generator/checker units 108 to 110. The CRC16 generator/checker units 108 to 110 perform the CRC calculation and check and output determination results (first, second and third determination results) obtained by determining whether a read error occurs to the phase adjuster 115. The CRC16 generator/checker unit 107 is a CRC generator/checker to perform CRC calculation (generation) and check (comparison) to data DAT1 to DATM other than the data DAT0 in synchronization with the first clock signal. Because 16-bit CRC code is appended to data transfers of data DAT1 to DATM, the CRC16 generator/checker unit 107 calculates 16-bit CRC code of one of data DAT1 to DATM to perform comparison. A data bus width (M+1) of buses 122 and 123 is determined depending on a specification of the memory card 102, for example, one of one, four and eight for a MMC (Multi Media Card), and one or four for a SD (Secure Digital) card. Although one bus 123 and one CRC16 generator/checker unit 107 are shown in FIG. 2 for simplification of explanation, in actual fact, the data transfers of the data DAT1 to DATM are executed by using a plurality of buses and CRC16 generator/checker units provided for each one bit of the data buses.

Although CRC16 generator/checker units to receive a three-phase clock signal may be provided with respect to data DAT1 to DATM, the configuration as shown in FIG. 2 only multiplexes CRC16 generator/checker units 108 to 110 for data DAT0 in order to set priority to a circuit size.

The control circuit 114 detects a reception end and instructs the phase adjuster 115 to compare phases. The reception ends at a timing at which the CRC16 generator/checker units 108 to 110 acquire the whole data block of the data DAT0, or a timing at which the CRC7 generator/checker units 111 to 113 acquire the whole data block of RR (Read Response), WR (Write Response), or NDR (No Data Response) when the data block contains response data.

The phase adjuster 115 adjusts the phase of the subsequent receive clock signal depending on the first, second and third determination results (generation/check results generated by three CRC generator/checker units). The phase adjuster 115 is notified of a timing for the phase adjustment by the control circuit 114. When a phase correction is required, the phase adjuster 115 instructs the receive clock generator 116 to change phases based on the notification from the control circuit 114.

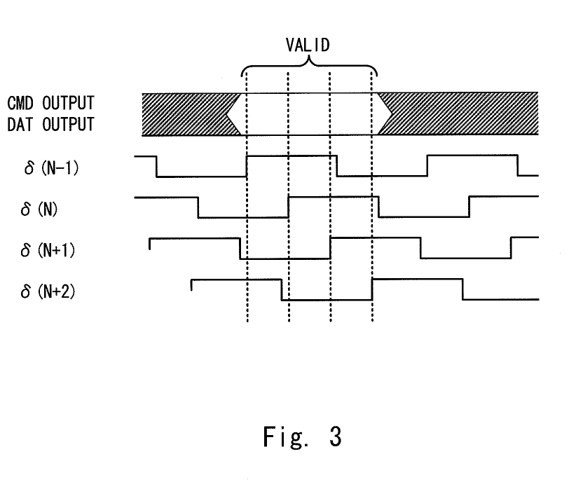

FIG. 3 is a view to explain a resolution capability to be needed for the phase adjustment. In this exemplary embodiment, the three-phase receive clock signal as an example of the receive clock signal is composed of three clock signals including the first clock signal, the second clock signal with the phase advanced with respect to the first clock signal, and the third clock signal with the phase delayed with respect to the first clock signal. It is preferable to ensure that there is a configuration to keep a three-phase receive clock signal within a data window by necessity. In FIG. 3, a data window period is shown as “VALID”. For this reason, the predetermined adjusting phase is set to be equal to or less than one third of a data window width.

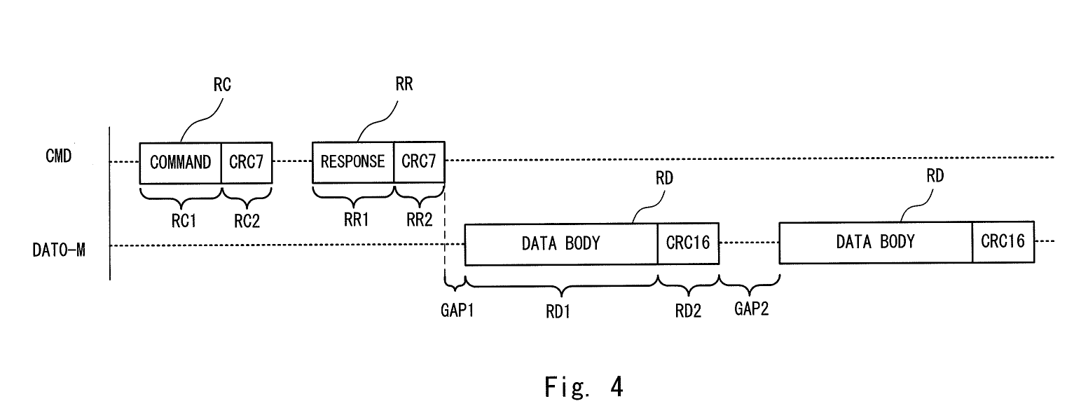

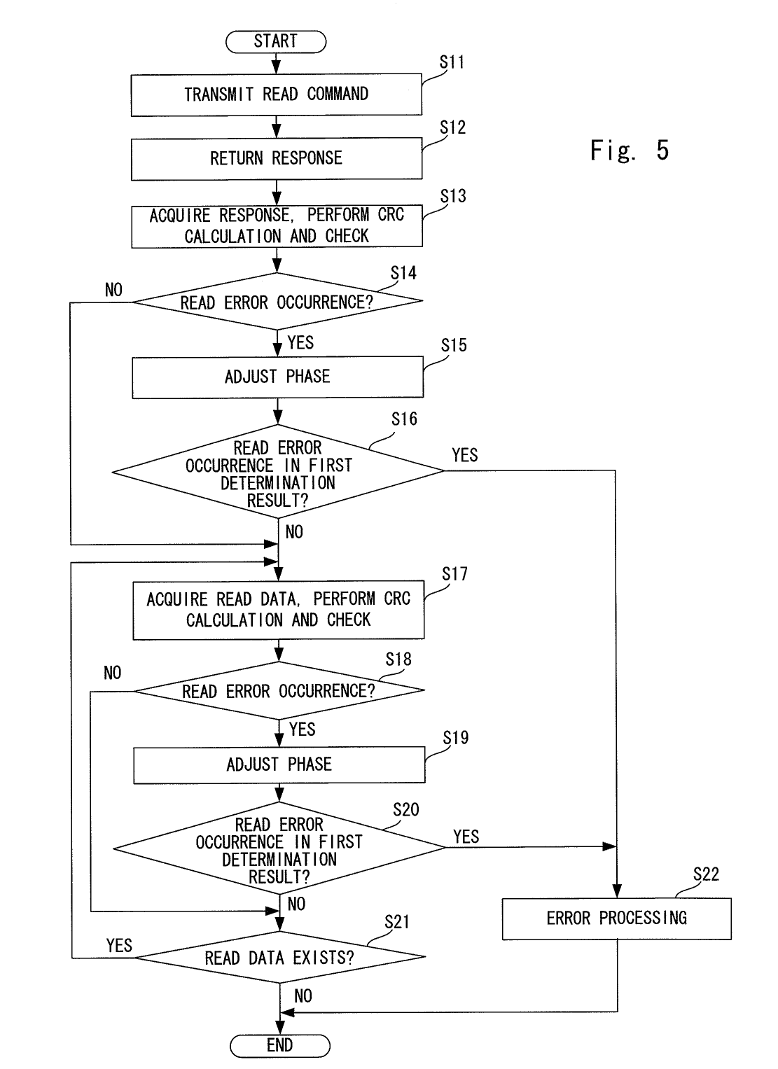

Subsequently, an operation of the host controller 101 will be described referring to FIGS. 4 and 5.

FIG. 4 is a pattern diagram showing a timing of a read operation to acquire the data block transferred from the memory card. A read command RC includes a read command (COMMAND) RC1 and a CRC unit (CRC7) RC2 of a 7-bit CRC code which is appended to the read command RC1. A response RR includes a response data (RESPONSE) RR1 and a CRC unit (CRC7) RR2 of a 7-bit CRC code which is appended to the response data RR1. The read command RC is the data block including the read command RC1 as the data body. The response RR is the data block including the response data RR1 as the data body. A data block RD includes a data body (DATA BODY) RD1 and a CRC unit (CRC16) RD2 of a 16-bit CRC code which is appended to the data body RD1. The data body of the data block RD is read data. For example, the data block RD of the memory card similar to the MMC and the SD card is composed of the data body RD1 and the CRC unit RD2 calculated by the data body RD1.

FIG. 5 is a flowchart showing an error detecting operation in the read operation to acquire the data block. An operation to acquire data is partly omitted in FIG. 5.

First, the host controller 101 transmits the read command RC to indicate a data transmission request to the memory card 102 (S11). Upon the read command RC, the memory card 102 returns the response RR to respond to the read command RC (S12).

The host controller 101 converts the response data RR1 of the response RR from serial data to parallel data by the serial/parallel converter 105 and stores it to the response register 106.

The host controller 101 sequentially performs a CRC calculation/update in the CRC7 generator/checker units 111 to 113 while receiving the read command RC. At this time, in the host controller 101, the CRC7 generator/checker units 111 to 113 detect a read error by comparing a CRC calculation result calculated using the response data RR1 and the CRC unit RR2 transmitted from the memory card 102 in a period to receive the CRC unit RR2 transferred subsequent to the response data RR1. Then, the host controller 101 outputs read error detection results (first, second and third determination results) detected by the CRC7 generator/checker units 111 to 113 to the phase adjuster 115 (S13).

A specific configuration of the CRC generator/checker uses a configuration represented by a specification of the MMC or the like. Here, an explanation of the specific configuration of the CRC generator/checker is omitted, but the CRC generator/checker includes flip-flops, the number of which being equal to the bit number of the CRC code. The flip-flops are configured to hold generation/check results after the completion of the input of the CRC unit by inputting the CRC unit RC2 subsequent to the read command RC1. When all flip-flops hold “0”, validation of the CRC unit succeeds (no read error occurrence). When at least one of the flip-flops holds “1”, validation of the CRC unit fails (read error occurrence).

When determining that there is a need to correct the phase of the receive clock signal based on the read error detection results, that is, there is a read error occurrence (YES in S14), the phase adjuster 115 outputs a control signal (UP or DOWN) to advance or delay the phase of the receive clock signal to the receive clock generator 116, and the receive clock generator 116 performs a phase change of the three-phase receive clock signal (S15). To avoid the phase change while receiving data, the receive clock generator 116 performs the phase change within a gap period “GAP1” shown in FIG. 4 existing between read data (specifically, between the response RR and the data block RD). This makes it possible to use adjusted receive clock signal when receiving the data block RD.

The read error detection result detected by the CRC7 generator/checker unit 112 operating in accordance with the first clock signal is transmitted to the control circuit 114. The control circuit 114 performs an error processing (S16 and S22). Specifically, when a read error is detected in the first determination result (YES in S16), the control circuit 114 instructs to discard contents of the process response register 106, to generate an interrupt processing to a CPU, or the like (S22). After that, the host controller 101 completes the processing. A detailed explanation of the error processing is omitted. After the error processing, the host controller 101 may return to the processing of step S11 to perform the read operation again. Note that, the CPU is arranged outside of the host controller 101 and is not shown in FIG. 2.

When it is determined that there is no read error (NO in S14 or S16), the memory card 102 starts to transfer the data block RD to the host controller 101.

The host controller 101 converts the data body RD1 from the serial data to the parallel data by the serial/parallel converter 103 and stores it to the read data buffer 104.

The host controller 101 sequentially performs a CRC calculation/update in the CRC16 generator/checker units 107 to 110 shown in FIG. 2 while receiving the data body RD1. At this time, in the host controller 101, the CRC16 generator/checker units 107 to 110 detect a read error by comparing a CRC calculation result calculated using the data body RD1 and the CRC unit RD2 transmitted from the memory card 102 in a period to receive the CRC unit RD2 transferred subsequent to the data body RD1. Then, the host controller 101 outputs read error detection results (first, second and third determination results) to the phase adjuster 115 (S17).

When determining that there is a need to correct the phase of the receive clock signal based on the read error detection results, that is, there is a read error occurrence (YES in S18), the phase adjuster 115 outputs a control signal (UP or DOWN) to advance or delay the phase to the receive clock generator 116, and the receive clock generator 116 performs the phase change of the three-phase receive clock signal (S19). To avoid the phase change while receiving data, the receive clock generator 116 performs the phase change within a gap period “GAP2” shown in FIG. 4 existing between the data blocks RD.

The read error detection results detected by the CRC16 generator/checker units 107 and 109 operating in accordance with the first clock signal is transmitted to the control circuit 114. The control circuit 114 performs the error processing (S20 and S22). Specifically, when a read error is detected in the first determination result (YES in S20), the control circuit 114 instructs to discard contents of the read data buffer 104, to generate an interrupt processing to a CPU, or the like (S22). After that, the host controller 101 completes the processing similarly to the case of YES in step S16.

When it is determined that there is no read error (NO in S18 or S20), the host controller 101 determines whether read data to be read exists in the memory card 102 (S21). When the read data to be read exists (YES in S21), the host controller 101 repeats the processing from steps S17 to S21 until there is no read data (NO in S21).

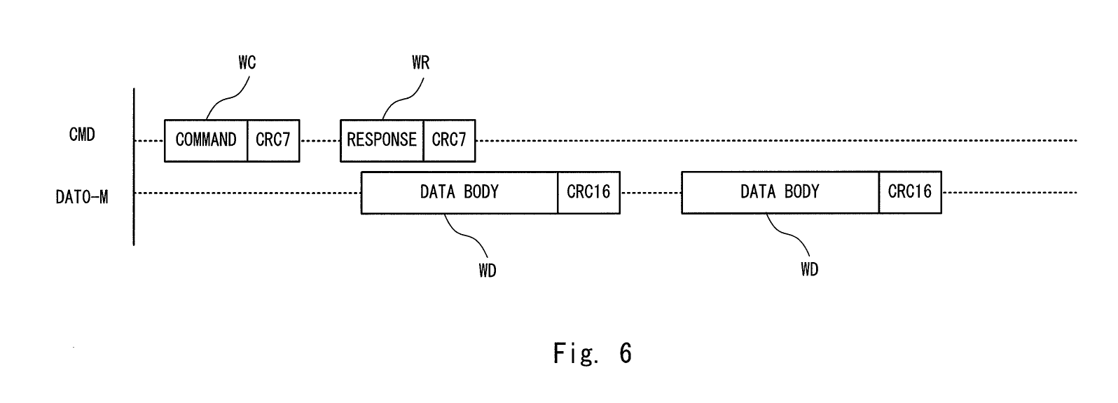

FIG. 6 is a pattern diagram showing a timing of a write operation to write the data block to the memory card. A write command WC includes a write command (COMMAND) and a CRC unit (CRC7) of a 7-bit CRC code which is appended to the write command. A response WR includes a response data (RESPONSE) and a CRC unit (CRC7) of a 7-bit CRC code which is appended to the response data. A data block WD includes a data body (DATA BODY) and a CRC unit (CRC16) of a 16-bit CRC code which is appended to the data body.

In the write operation, because the data block WD is transferred from the host controller 101 to the memory card 102, it is impossible to correct the phase of the receive clock signal using the data block WD. Instead, it is possible to correct the phase of the receive clock signal in the similar way as the read operation using a read error detection result of the response WR responding to the write command WC.

A correction method using the read error detection result of the response WR uses the CRC7 generator/checker units 111 to 113. An operation of a phase correction using the read error detection of the response WR is similar to the operations from steps S13 to S16, and S22 of FIG. 5. Operations of the control circuit 114, the phase adjuster 115, and the receive clock generator 116 are similar to the operations of receiving data from the memory card 102.

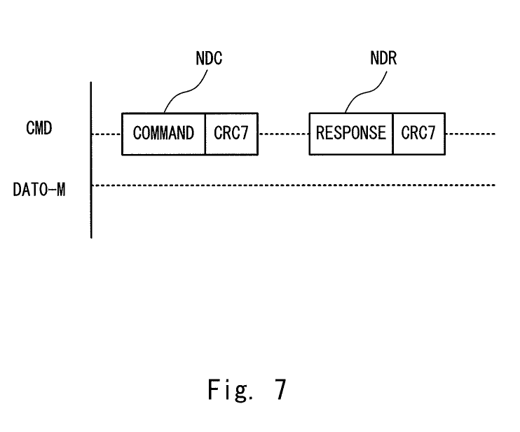

The phase adjustment of the receive clock signal using the response from the memory card 102 may be applied to an access operation without data transfer as shown in FIG. 7. FIG. 7 is a pattern diagram showing a timing of the access operation without data transfer to the memory card. FIG. 7 shows an example where the host controller 101 transmits a command NDC (No Data Command) to the memory card 102 and the memory card 102 returns a response NDR with respect to the command NDC to the host controller 101. A read error detection result of the response NDR is similar to the read error detection result of the response WR.

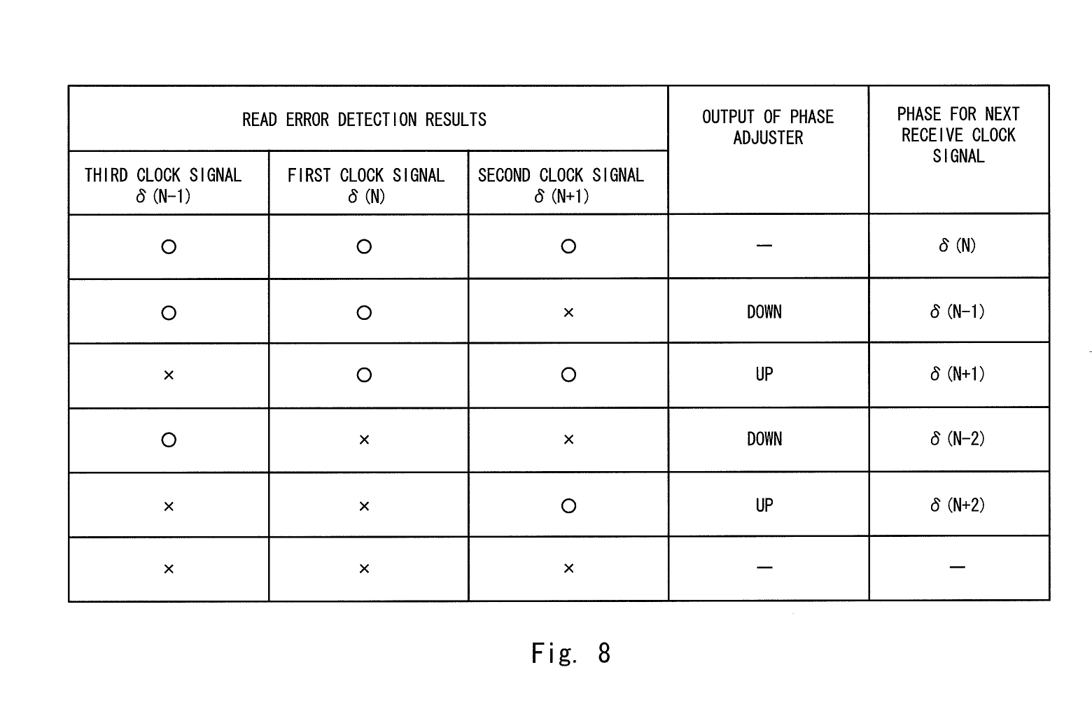

FIG. 8 is a view to explain a phase adjustment example of the first, second and third clock signals. FIG. 8 shows the case of a three-phase receive clock signal as the example of the receive clock signal including the first clock signal (the clock signal line 118), the second clock signal with the phase advanced (the clock signal line 119), and the third clock signal with the phase delayed (the clock signal line 120).

When a read error is not detected by any of the CRC generator/checker (CRC16 generator/checker units 108 to 110, CRC7 generator/checker units 111 to 113) which operate in accordance with the three-phase receive clock signal, the phase adjustment is not performed because it is determined that the three-phase receive clock signal exists fully inside the data window.

When a read error is detected in a CRC calculation result of the CRC generator/checker which operates in accordance with the third clock signal, it is determined that the phase of the three-phase receive clock signal is delaying. Therefore, the second clock signal with the phase advanced is selected as a next first receive clock signal in order to correct the three-phase receive clock signal to be further inside the data window.

When a read error is detected in a CRC calculation result of the CRC generator/checker which operates in accordance with the second clock signal, it is determined that the phase of the three-phase receive clock signal is advancing. Therefore, the third clock signal with the phase delayed is selected as the next first receive clock signal in order to correct the three-phase receive clock signal to be further inside the data window.

When read errors are detected in CRC calculation results of the first and third clock signals, it is determined that the phase of the three-phase receive clock signal is delaying. Therefore, a clock signal δ(N+2) is selected as the next first receive clock signal in order to correct the three-phase receive clock signal to be at a center of the data window. The clock signal δ(N+2) is obtained by shifting the phase of the present first clock signal by twice the amount of the predetermined adjusting phase. Note that, because the read errors are detected in the CRC calculation result of the first receive clock signal, the same data will be read.

When read errors are detected in CRC calculation results of the first and second clock signals, it is determined that the phase of the three-phase receive clock signal is advancing. Therefore, a clock signal δ(N−2) is selected as the next first receive clock signal in order to correct the three-phase receive clock signal to be at a center of the data window. The clock signal δ(N−2) is obtained by shifting the phase of the present first clock signal by twice the amount of the predetermined adjusting phase. Note that, because the read errors are detected in the CRC calculation result of the first receive clock signal, the same data will be read.

Further, when read errors are detected in CRC calculation results of the first, second and third clock signals, a re-tuning of an initial phase of the three-phase receive clock signal is performed. In a memory card initialization, it is need to search an initial phase in order to arrange the phase of the receive clock signal in a center of the data window. In this example, the phase of the first clock signal is arranged in the center. When errors are detected in all of the three-phase receive clock signal, the re-search of the initial phase and the re-tuning is performed. Details of the re-search of the initial phase and the re-tuning are omitted.

Note that the DATA 1 to DATM may be triplicated as well as the data DAT0, that is, configured to receive data in accordance with the three-phase receive clock signal. By triplicating for the DAT0 to DATM, a retry (retransfer) is not needed even when read errors are detected in at least two of the CRC calculation results of the first, second and third clock signals shown in FIG. 8. However, a problem arises that a circuit size increases. Therefore, this exemplary embodiment shows the exemplary configuration where only the DAT0 is triplicated. Only the DAT0 is multiplied based on a consideration of a possibility of occurrence of two-step shifting and the circuit size.

Accordingly, when data is read from the memory card 102, read error detections are performed by using, in addition to the first clock signal used as the receive clock signal, the second clock signal with the phase advanced with respect to the first clock signal and the third clock signal with the phase delayed with respect to the first clock signal. This makes it possible to determine whether the phase of the first clock signal is optimal with respect to the data window. Depending on this determination result, adjustments of the first clock signal used for reading subsequent data are performed continuously. As a result, it is possible to suppress a read error occurrence.

As described above, the host controller 101 of this exemplary embodiment achieves an interface to transfer the data block including the data body and the CRC code using the base clock signal. The memory card control device 300 serially receives the data blocks by the first, second and third clock signals as described above and calculates CRC codes of each data of the received data blocks. Thus, the phase calibration circuit that compares the calculated CRC codes and the CRC codes included in the data block and adjusts the phase difference between the first, second and third clock signals and the base clock signal are implemented according to the comparison results.

Therefore, it is possible to perform the phase adjustment of the receive clock signal (the first clock signal) for each reception of the data block and to suppress a read error occurrence. There is no need to set the particular adjustment period to correct the phase of the receive clock signal. As a result, it is possible to suppress the degradation of data transfer efficiency.

### Second Exemplary Embodiment

While the first exemplary embodiment employs the memory card which uses CRC codes as the error detection method for the data block, such as the MMC or the SD card, a calibration system of this invention can be easily applied to a data block transfer means which uses different error detection method. For example, an error detection method which uses a data block represented by a format including a data body (such as RD1 shown in FIG. 4) and a redundant block (RD2) calculated by the data body may be used. It is possible to use general error detecting code or a portion of error correcting codes. In particular, a parity code, a check sum, a hash value, or the like may be used as the error detecting code. A BCH code, a hamming code, or the like may be used as an error correcting code. Instead of using the method to append redundant data such as the error correcting code as described above, other methods may be used such as a method to use error correcting codes which enable to inform the phase adjuster 115 of a read error occurrence like the CRC16 generator/checker units 111 to 113 as shown in FIG. 2. In this case, it is only required that an error occurrence is detected by encoding results of data after data reception and comparison results (first, second and third determination results) are sent to the phase adjuster 115.

### Third Exemplary Embodiment

In the first exemplary embodiment, a synchronous memory card is assumed, but this invention may be easily applied to a device and a method which employ a memory specification where a data output delay from the memory card is specified by more than one clock cycle. For example, it is assumed that a phase adjustment range is 360°. In this case, even when there is no correlation between a data output delay and an operation clock signal, it is possible to receive data by adjusting a sampling point to an arbitrary angle by setting the phase adjustment range to 360°. Further, even when the data output delay wobbles, it is possible to correct the phase of the receive clock signal and to continue data reception.

### Other Exemplary Embodiments

Although the case where the receive clock generator 310 (receive clock generator 116) uses the three receive clock signals is explained in each of the exemplary embodiment, the receive clock generator 310 may generate more than three clock signals. In this case, the determination unit 320 determines the acquired data blocks by using more than three clock signals and outputs more than three determination results to the phase adjustment unit 330. Then the phase adjustment unit 330 adjusts the phase by using the more than three determination results.

According to each of the exemplary embodiments, in a high-speed data interface including an error detecting function, it is possible to perform the phase adjustment of the receive clock signal continuously by detecting a read error of receive data using the three-phase receive clock signal having different phases. This makes it possible to suppress a read error occurrence and to eliminate a particular calibration period. As a result, it is possible to suppress the degradation of transfer efficiency.

While the invention has been described in terms of several exemplary embodiments, those skilled in the art will recognize that the invention can be practiced with various modifications within the spirit and scope of the appended claims and the invention is not limited to the examples described above.

Each of the exemplary embodiments can be combined as desirable by one of ordinary skill in the art.

Further, the scope of the claims is not limited by the exemplary embodiments described above.

Furthermore, it is noted that, Applicant's intent is to encompass equivalents of all claim elements, even if amended later during prosecution.

What is claimed is:

1. A phase calibration circuit comprising:
a receive clock generator that generates a plurality of clock signals including at least a first clock signal with a phase shifted with respect to a base clock signal, a second clock signal with a phase advanced with respect to the first clock signal, and a third clock signal with a phase delayed shift with respect to the first clock signal;
a determination unit that acquires data blocks, each of which including a data body and detection information for detecting an error, in accordance with the plurality of clock signals, determines whether an error occurs by using the detection information, and outputs a plurality of determination results including at least a first determination result obtained by determining a data block acquired in accordance with the first clock signal, a second determination result obtained by determining a data block acquired in accordance with the second clock signal, and a third determination result obtained by determining a data block acquired in accordance with the third clock signal; and
a phase adjustment unit that instructs the receive clock generator to adjust a phase of the first clock signal depending on the plurality of the determination results.

2. The phase calibration circuit according to claim 1, wherein the phase adjustment unit instructs to delay the phase of the first clock signal when the second determination result indicates an error occurrence, and to advance the phase of the first clock signal when the third determination result indicates an error occurrence.

3. The phase calibration circuit according to claim 1, wherein the receive clock generator generates the second clock signal by advancing the phase of the first clock signal by a predetermined adjusting phase and the third clock signal by delaying the phase of the first clock signal by the predetermined adjusting phase.

4. The phase calibration circuit according to claim 2, wherein wherein the receive clock generator generates the second clock signal by advancing the phase of the first clock signal by a predetermined adjusting phase and the third clock signal by delaying the phase of the first clock signal by the predetermined adjusting phase.

5. The phase calibration circuit according to claim 3, wherein the receive clock generator delays the phase of the first clock signal by the predetermined adjusting phase when receiving an instruction to delay the phase of the phase of the first clock signal, and advances the phase of the first clock signal by the predetermined adjusting phase when receiving an instruction to advance the phase of the first clock signal.

6. The phase calibration circuit according to claim 4, wherein the receive clock generator delays the phase of the first clock signal by the predetermined adjusting phase when receiving an instruction to delay the phase of the phase of the first clock signal, and advances the phase of the first clock signal by the predetermined adjusting phase when receiving an instruction to advance the phase of the first clock signal.

7. The phase calibration circuit according to claim 3, wherein the predetermined adjusting phase is one third or less of a data window width.

8. The phase calibration circuit according to claim 4, wherein the predetermined adjusting phase is one third or less of a data window width.

9. The phase calibration circuit according to claim 5, wherein the predetermined adjusting phase is one third or less of a data window width.

10. The phase calibration circuit according to claim 6, wherein the predetermined adjusting phase is one third or less of a data window width.

11. The phase calibration circuit according to claim 1, wherein
the data block includes one of response data to respond to a command transmitted to a memory card and read data read from the memory card as the data body, and
the determination unit comprises:
a first response data determination unit that acquires a data block including the response data in accordance with the first clock signal, determines whether an error occurs by using the detection information, and outputs a determination result as the first determination result;
a second response data determination unit that acquires the data block including the response data in accordance with the second clock signal, determines whether an error occurs by using the detection information, and outputs a determination result as the second determination result;
a third response data determination unit that acquires the data block including the response data in accordance with the third clock signal, determines whether an error occurs by using the detection information, and outputs a determination result as the third determination result;
a first read data determination unit that acquires a data block including the read data in accordance with the first clock signal, determines whether an error occurs by using the detection information, and outputs a determination result as the first determination result;
a second read data determination unit that acquires the data block including the read data in accordance with the second clock signal, determines whether an error occurs by using the detection information, and outputs a determination result as the second determination result; and
a third read data determination unit that acquires the data block including the read data in accordance with the third clock signal, determines whether an error occurs by using the detection information, and outputs a determination result as the third determination result;

12. The phase calibration circuit according to claim 1, wherein the phase adjustment unit instructs the receive clock generator to adjust the phase of the first clock signal before the determination unit acquires another data block after acquiring one data block.

13. The phase calibration circuit according to claim 1, wherein
the detection information is an error detecting code appended to the data body, and
the determination unit determines whether an error occurs by comparing a calculation result of the data block and the error detecting code.

14. The phase calibration circuit according to claim 13, wherein
one of a cyclic redundancy check code, a parity code, a check sum, and a hash value is used as the error detecting code.

15. The phase calibration circuit according to claim 1, wherein
the detection information is an error correcting code appended to the data body, and
the determination unit determines whether an error occurs by using a calculation result of the data block and the error correcting code.

16. A memory card control device comprising:
the phase calibration circuit according to claim 1; and
a memory holding a data body.

17. A phase calibration method comprising:
generating a plurality of clock signals including at least a first clock signal with a phase shifted with respect to a base clock signal, a second clock signal with a phase advanced with respect to the first clock signal, and a third clock signal with a phase delayed with respect to the first clock signal;
acquiring data blocks, each of which including a data body and detection information for detecting an error, in accordance with the plurality of clock signals;
determining whether an error occurs by using the detection information;
outputting a plurality of determination results including at least a first determination result obtained by determining a data block acquired in accordance with the first clock signal, a second determination result obtained by determining a data block acquired in accordance with the second clock signal, and a third determination result obtained by determining a data block acquired in accordance with the third clock signal; and
adjusting a phase of the first clock signal depending on the plurality of the determination results.
